(19) United States
(12) Patent Application Publication
(10) Pub. No.: US 2015/0200275 A1
(43) Pub. Date: Jul. 16, 2015

(54) FINFET AND METHOD FOR MANUFACTURING THE SAME

(71) Applicant: INSTITUTE OF MICROELECTRONICS, CHINESE ACADEMY OF SCIENCES, Beijing (CN)

(72) Inventors: Huilong Zhu, Poughkeepsie, NY (US); Miao Xu, Beijing (CN); Qingqing Liang, Lagrangeville, NY (US); Haizhou Yin, Poughkeepsie, NY (US)

(21) Appl. No.: 14/585,053

(22) Filed: Dec. 29, 2014

Related U.S. Application Data
(63) Continuation of application No. PCT/CN2012/085634, filed on Nov. 30, 2012.

(30) Foreign Application Priority Data
Nov. 9, 2012 (CN) 201210447946.3

(51) Int. Cl. H01L 29/66; H01L 29/49; H01L 29/78

(52) U.S. Cl. CPC H01L 29/66795; H01L 29/785; H01L 29/4925

(57) ABSTRACT

A FinFET with reduced leakage between source and drain regions, and a method for manufacturing the FinFET are disclosed. In one aspect, the method includes forming, on a semiconductor substrate, at least two openings to define a semiconductor fin. The method also includes forming a gate dielectric layer that conformally covers the fin and the openings. The method also includes forming, within the openings, a first gate conductor adjacent to the bottom of the fin. The method also includes forming, within the openings, an insulating isolation layer on the first gate conductor. The method also includes forming a second gate conductor on the fin and on the insulating isolation layer adjacent to the top of the fin. The method also includes forming spacers on sidewalls of the second gate conductor. The method also includes forming a source region and a drain region in the fin.

### RELATED APPLICATIONS

This application claims priority to International Application No. PCT/CN2012/085634, filed on Nov. 30, 2012, entitled “FINFET AND MANUFACTURING METHOD THEREFOR,” and Chinese Application No. 201210447946.3, filed on Nov. 9, 2012, which are incorporated herein by reference in their entirety.

### BACKGROUND

1. Field

The disclosed technology relates to semiconductor technology, and particularly, to FinFETs and methods for manufacturing the same.

2. Description of the Related Technology

With size reduction of planar-type semiconductor devices, short channel effect becomes increasingly obvious. In order to address problems caused by the short channel effect, three-dimensional semiconductor devices such as Fin Field Effect Transistors (FinFETs) have been proposed. The FinFET comprises a semiconductor fin forming a channel region and a gate stack covering at least a sidewall of the semiconductor fin. The gate stack intersects the semiconductor fin and comprises a gate conductor and a gate dielectric. The gate dielectric isolates the gate conductor from the semiconductor fin. The FinFET may have a double-gate, a tri-gate, or an annular-gate configuration. The semiconductor fin has a small width (i.e., thickness), and thus the FinFET can improve control of carriers in the channel region by the gate conductor and suppress the short-channel effect.

The FinFET may be manufactured on a bulk silicon substrate or a Silicon-on-Insulator (SOI) wafer. The FinFET based on the bulk silicon substrate has an advantage of low cost in massive production. However, the semiconductor substrate under the semiconductor fin may provide a leakage path between a source region and a drain region, causing performance deterioration or even failure of the device. Therefore, there is a need for FinFET devices that reduce leakage between the source and drain regions via the semiconductor substrate.

### SUMMARY OF CERTAIN INVENTIVE ASPECTS

One aspect of the disclosed technology includes a FinFET capable of reducing the leakage between the source region and the drain region.

One aspect of the disclosed technology includes a method for manufacturing a FinFET. The method includes forming, on a semiconductor substrate, at least two openings to define a semiconductor fin. The method also includes forming a first gate dielectric layer that conformally covers the semiconductor fin and the at least two openings. The method also includes forming within the at least two openings a first gate conductor adjacent to a bottom of the semiconductor fin. The method also includes forming within the at least two openings an insulating isolation layer arranged on the first gate conductor. The method also includes forming a second gate conductor having a first portion on the insulating isolation layer, the first portion adjacent to a top of the semiconductor fin, and the second gate conductor having a second portion on the semiconductor fin. The method also includes forming spacers on sidewalls of the second gate conductor. The method also includes forming a source region and a drain region in the semiconductor fin.

Another aspect of the disclosed technology includes a FinFET. The FinFET includes a semiconductor substrate. The FinFET also includes a semiconductor fin formed in the semiconductor substrate. The FinFET also includes source/drain regions arranged at opposite ends of the semiconductor fin. The FinFET also includes a gate dielectric layer arranged on the semiconductor fin. The FinFET also includes a first gate conductor adjacent to a bottom of the semiconductor fin. The FinFET also includes an insulating isolation layer arranged on the first gate conductor. The FinFET also includes a second gate conductor having a first portion on the insulating isolation layer and adjacent to a top of the semiconductor fin and a second portion on the semiconductor fin. The FinFET also includes spacers arranged on sidewalls of the second gate conductor.

### BRIEF DESCRIPTION OF THE DRAWINGS

The foregoing and other objects, features, and advantages of the disclosed technology will become more apparent from the following description of embodiments when read in conjunction with the accompanying drawings, in which:

FIG. 1 illustrates a sectional view of a FinFET along one direction in a process flow of a method for manufacturing a FinFET in accordance with an embodiment of the disclosed technology;

FIG. 2 illustrates a sectional view of a FinFET along one direction in a process flow of a method for manufacturing a FinFET in accordance with an embodiment of disclosed technology;

FIG. 3 illustrates a sectional view of a FinFET along one direction in a process flow of a method for manufacturing a FinFET in accordance with an embodiment of the disclosed technology;

FIG. 4 illustrates a sectional view of a FinFET along one direction in a process flow of a method for manufacturing a FinFET in accordance with an embodiment of the disclosed technology;

FIG. 5 illustrates a sectional view of a FinFET along one direction in a process flow of a method for manufacturing a FinFET in accordance with an embodiment of the disclosed technology;

FIG. 6 illustrates a sectional view of a FinFET along one direction in a process flow of a method for manufacturing a FinFET in accordance with an embodiment of the disclosed technology;

FIG. 7A illustrates a sectional view of a FinFET along one direction in a process flow of a method for manufacturing a FinFET in accordance with an embodiment of the disclosed technology;

FIG. 7B illustrates a top view of a FinFET along one direction in a process flow of a method for manufacturing a FinFET in accordance with an embodiment of the disclosed technology and a position where the sectional views are taken;

FIG. 8A illustrates a sectional view of a FinFET along one direction in a process flow of a method for manufacturing a FinFET in accordance with an embodiment of the disclosed technology;

FIG. 8B illustrates a top view of a FinFET along one direction in a process flow of a method for manufacturing a FinFET in accordance with an embodiment of the disclosed technology and a position where the sectional views are taken; and

FIG. 9 illustrates a perspective view of a FinFET in accordance with an embodiment of the disclosed technology;

FIG. 10 illustrates a simulation result of a transfer characteristic curve (Id-Vg) of a FinFET in accordance with an embodiment of the disclosed technology; and

FIG. 11 is a flowchart illustrating a method for manufacturing a FinFET device according to the disclosed technology.

### DETAILED DESCRIPTION OF CERTAIN EMBODIMENTS

Next, the disclosed technology will be explained in detail with reference to the drawings. Similar components throughout the drawings are indicated by similar reference numbers. The drawings are not drawn to scale for purpose of clarity.

A semiconductor structure obtained after several steps may be illustrated in a single figure for conciseness.

It will be understood that, in describing a structure of a device, when a layer or region is referred to as being arranged “on” or “above” another layer or region, the layer or region may be directly on or above the other layer or region, or there may be one or more other layers or regions sandwiched therebetween. When the device is turned over, the layer or region will be “under” or “below” the other layer or region. If the layer or region is to be directly arranged on the other layer or region, it will be described as “directly on” or “on and in contact with” the other layer or region.

In the disclosed technology, terminology “semiconductor structure” generally refers to a structure that has been formed after respective steps in manufacturing the semiconductor device and comprises all of the layers or regions that have been formed. Various specific details of the disclosed technology, such as structures, materials, sizes, and manufacturing processes and technologies of the device, will be described in the following to facilitate understanding of the disclosed technology. However, one of ordinary skill in the art will understand that the disclosed technology can be implemented without theses specific details.

Unless otherwise particularly indicated, parts of a FinFET may be formed of materials known to one of ordinary skill in the art. For some embodiments, a semiconductor material may comprise a Group III-V semiconductor material, such as GaAs, InP, GaN, and SiC, or a Group IV semiconductor material, such as Si or Ge. For some embodiments, a gate conductor may comprise a conductive material, such as any one selected from a group consisting of metal, doped polysilicon, a stack of metal and doped polysilicon, and any other conductive material including, e.g., any one selected from a group consisting of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni₃Si, Pt, Ru, Ir, Mo, HfRu, and RuOx. The gate conductor may also be any combination of the foregoing conductive materials. A gate dielectric may comprise SiO₂ or any other material having a dielectric constant larger than that of SiO₂. Such material may comprise, e.g., any one selected from a group consisting of oxide, nitride, oxynitride, silicide, aluminate, and titanate. The oxide may comprise, e.g., any one selected from a group consisting of SiO₂, HfO₂, ZrO₂, Al₂O₃, TiO₂, and La₂O. The nitride may comprise, e.g., Si₃N₄. The silicide may comprise, e.g., HfSiOₓ. The aluminate may comprise, e.g., LaAlO₃. The titanate may comprise, e.g., SrTiO₃. The oxynitride may comprise, e.g., SiON. The gate dielectric may comprise any suitable material known to one of ordinary skill in the art or a suitable material that might be invented in the future.

The disclosed technology can be implemented in various ways, some examples of which will be described as follows.

According to an embodiment of the method of the disclosed technology, steps as illustrated in FIGS. 1-6, 7A, and 8A are performed, in which figures sectional views of semiconductor structures obtained at respective stages are shown.

As illustrated in FIG. 1, a semiconductor substrate 101 is provided. The semiconductor substrate 101 may be, for example but not limited to, a bulk semiconductor substrate, e.g., a bulk-Si substrate, a Silicon on Insulator (SOI) substrate, or a SiGe substrate, etc. For the purpose of illustration, the bulk-Si substrate is taken as an example of the semiconductor substrate in the following description.

Next, the semiconductor substrate 101 is patterned to form a semiconductor fin 102. The patterning may comprise: forming a patterned photoresist mask PR1 on the semiconductor substrate 101 by photolithography comprising exposure and development; and removing exposed portions of the semiconductor substrate 101 through dry etching, such as ion milling, plasma etching, reactive ion etching, and laser ablation, or wet etching using an etching agent solution, in order to form at least two openings for defining the semiconductor fin 102. By controlling the etching time, it is possible to etch the semiconductor substrate 101 to a desired depth and thus control a height of the semiconductor fin 102.

It should be noted that although only one semiconductor fin 102 is shown in the drawings, the disclosed technology is not limited thereto. A plurality of semiconductor fins may be formed for a FinFET simultaneously. The plurality of semiconductor fins may be advantageous in increasing a turn-on current, for example.

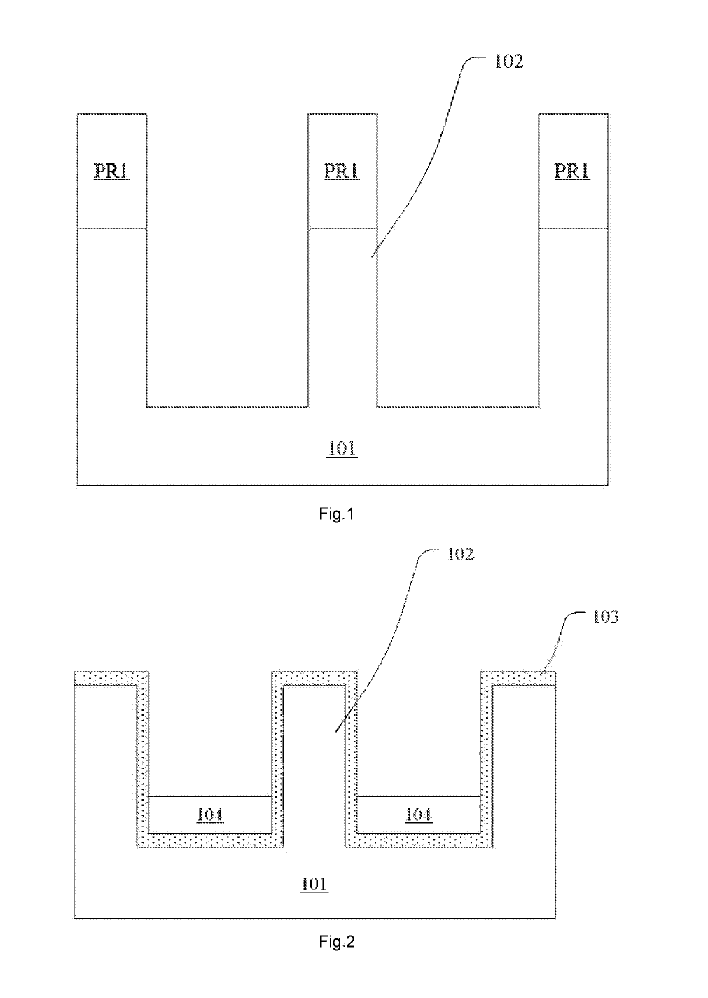

Next, the photoresist mask PR1 is removed by being ashed or dissolved in a solution. Then, a high-k dielectric layer 103 is formed conformally with a polysilicon layer 104 overlaid thereon on a surface of the semiconductor structure by a known deposition process, such as Chemical Vapor Deposition (CVD), Physical Vapor Deposition (PVD), Atom Layer Deposition, or sputtering,. The high-k dielectric layer 103 may be, e.g., an HfO₂ layer having a thickness of 5-10 nm. The polysilicon layer 104 should have a thickness sufficient to fill the openings. A portion of the polysilicon 104 is selectively removed with respect to the underlying high-k dielectric layer 103 through selective dry etching or wet etching, such as Reactive Ion Etching (ME), as shown in FIG. 2. By controlling the etching time, portions of the polysilicon layer 104 outside the openings are removed, and portions of the polysilicon layer 104 inside the openings are etched back. As a result, the remaining portions of the polysilicon layer 104 inside the openings form a first gate conductor, as shown in FIG. 2.

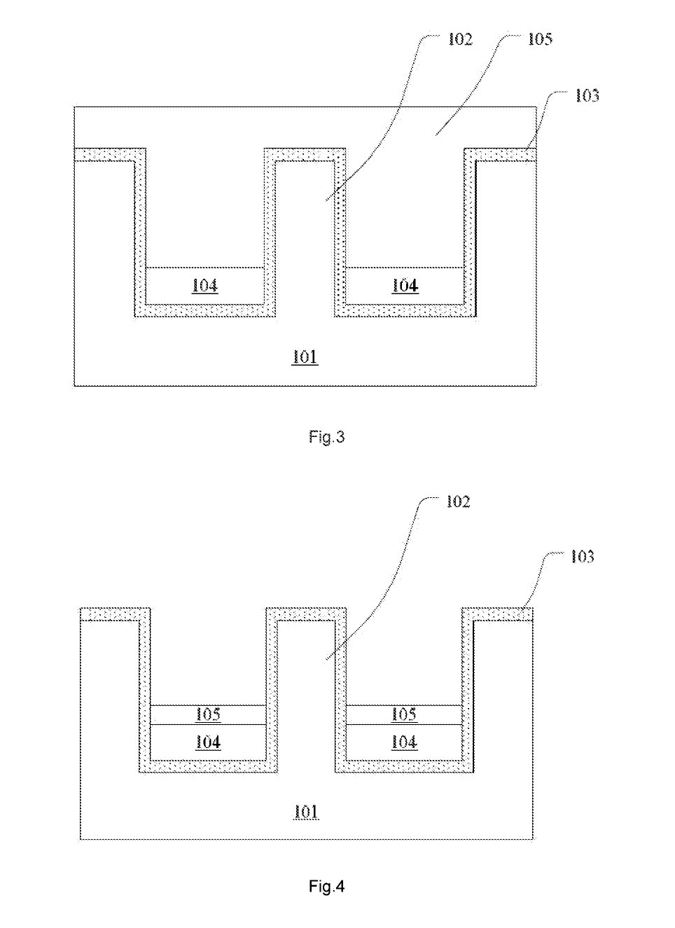

Next, an oxide layer 105 is formed on a surface of the semiconductor structure by a High Density Plasma (HDP) deposition process, as shown in FIG. 3. By controlling parameters of the deposition process, a portion of the oxide layer 105 on a top of the semiconductor fin has a thickness much smaller than that of portions of the oxide layer 105 within the openings. For some embodiments, the portion of the oxide layer 105 on the top of the semiconductor fin has a thickness smaller than ⅓ of the thickness of the portions of the oxide layer 105 within the openings. For example, the portion of the oxide layer 105 on the top of the semiconductor fin may have a thickness of approximately ¼ of the thickness of the portions of the oxide layer 105 within the openings. For some embodiments, the portion of the oxide layer 105 on the top of the semiconductor fin has a thickness smaller than half of the width of each opening. In an embodiment of the disclosed technology, the portion of the oxide layer 105 within each opening has a thickness greater than 80 nm, and the portion of the oxide layer 105 on the top of the semiconductor fin has a thickness smaller than 20 nm.

By selective dry etching or wet etching, such as Reactive Ion Etching (ME), the oxide layer 105 is etched back with respect to the high-k dielectric layer 103. By controlling the etching time, the portion of the oxide layer 105 on the top of the semiconductor fin is entirely removed and the portions of the oxide layer 105 within the openings are partly removed.

As a result, the etched oxide layer 105 is arranged on only the polysilicon layer 104 within each opening and has a thickness of, e.g., about 10-20 nm, as shown in FIG. 4. The oxide layer 105 comprises, e.g., silicon oxide and is configured as an insulating layer for separating a second gate conductor to be formed from the first gate conductor which has been formed.

Next, the second gate conductor 106 is formed on a surface of the semiconductor substrate by the above-described known deposition process, as shown in FIG. 5. The second gate conductor 106 should have a thickness sufficient to fill the openings and cover the semiconductor fin 102. The surface of the semiconductor structure may be planarized by Chemical Mechanical Polishing (CMP), if it is desired.

For some embodiments, before the second gate conductor 106 is formed, exposed portions of the high-k dielectric layer 103 may be removed and a conformal high-k dielectric layer (e.g., HfO₂, not shown) having a thickness of about 2-5 nm may be formed to provide an additional high-quality gate dielectric, which covers the semiconductor fin 102 and the openings conformally.

For some embodiments, before the second gate conductor 106 is formed, a conformal interface layer (e.g., silicon oxide, not shown) having a thickness of about 0.3-0.7 nm and a conformal high-k dielectric layer (e.g., HfO₂, not shown) having a thickness of about 2-5 nm may be formed to provide an additional high-quality gate dielectric.

For some embodiments, before the second gate conductor 106 is formed, a work function adjustment layer (not shown) may be formed. The work function adjustment layer may comprise, e.g., one of TaC, TiN, TaTbN, TaErN, TaYbN, TaSiN, HfSiN, MoSiN, RuTa, NiTa, MoN, TiSiN, TiCN, TaAlC, TiAlN, TaN, PtSi, Ni₃Si, Pt, Ru, Ir, Mo, HfRu, or RuOₓ, or any combinations thereof. The work function adjustment layer may have a thickness of about 2-10 nm. One of ordinary skill in the art will understand that the work function adjustment layer is optional. A gate stack comprising the work function adjustment layer, e.g., HfO₂/TiN/polysilicon, may advantageously achieve a decreased gate leakage current.

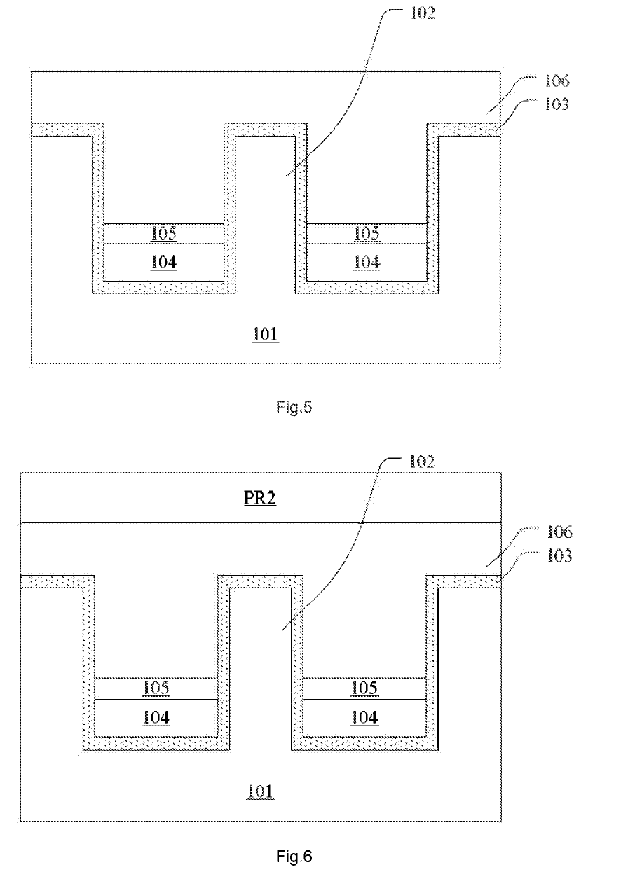

Next, the second gate conductor 106 is patterned as desired through the above-described patterning process using a photoresist mask PR2, as shown in FIG. 6. The patterned second gate conductor 106 intersects the semiconductor fin and extends, e.g., along a direction perpendicular to a length direction of the semiconductor fin 102. In the patterning, exposed portions of the second gate conductor 106 are selectively removed with respect to the underlying high-k dielectric layer 103 and the oxide layer 105.

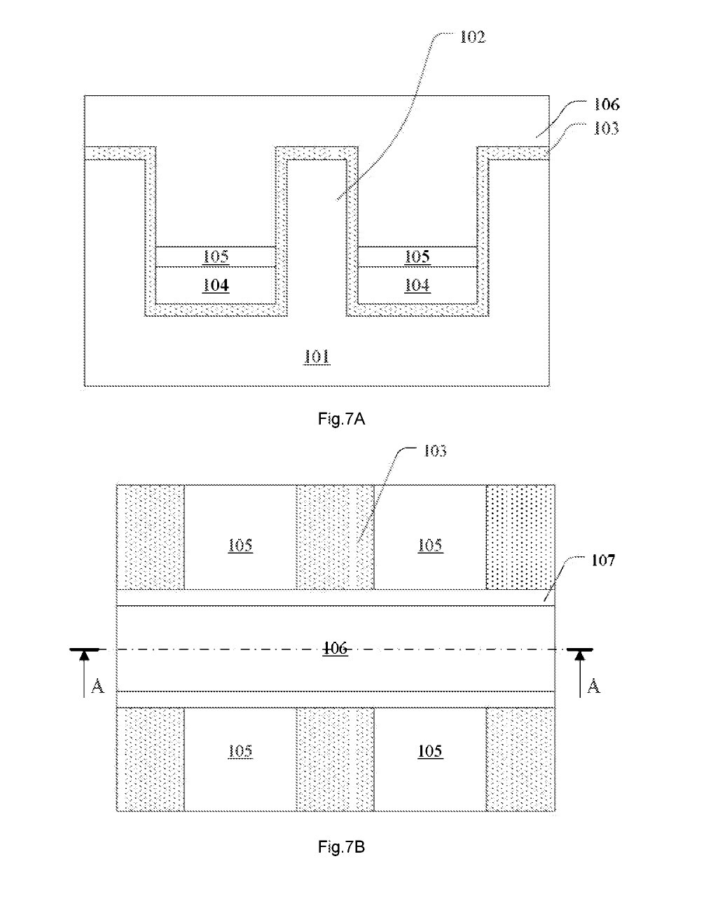

Next, the photoresist mask PR2 is removed by being ashed or dissolved in a solution, in order to expose a surface of the second gate conductor 106. Then, a nitride layer having a thickness of, e.g., 10-50 nm is deposited on a surface of the semiconductor structure through the above-described known deposition process. A portion of the nitride layer that extends in parallel with a main surface of the semiconductor substrate 101 is removed by anisotropic etching. Portions of the nitride layer that extend vertically on sidewalls of the second gate conductor 106 are retained to form spacers 107, as shown in FIGS. 7A and 7B.

FIG. 7B is a top view of a resulting semiconductor structure, wherein FIGS. 1-6, 7A and 8A are taken along a line A-A. FIGS. 1-6, 7A and 8A are sectional views taken along a direction perpendicular to the length direction of the semiconductor fin 102 and traversing the second gate conductor 106.

Then, source/drain regions (not shown) are formed by conducting ion implantation in the semiconductor fin 102 through the high-k dielectric layer 103 by using the second gate conductor 106 and the spacers 107 as a hard mask. During the ion implantation for forming the source/drain regions, for a p-type device, p-type dopants such as In, BF2, or B may be implanted, while for an n-type device, n-type dopants such as As or P may be implanted.

Additional ion implantations may be conducted to form extension and halo regions if desired. In the additional ion implantation for forming the extension regions, for the p-type device, the p-type dopants as described above may be implanted, while for the n-type device, the n-type dopants as described above may be implanted. In the additional ion implantation for forming the halo regions, for the p-type device, the n-type dopants as described above may be implanted, while for the n-type device, the p-type dopants as described above may be implanted.

For some embodiments, after the above-described ion implantation, the implanted dopants may be activated by annealing such as spike annealing, laser annealing, or rapid annealing, etc.

Next, exposed portions of the high-k dielectric layer 103 are selectively removed through the above-described dry etching or wet etching such as ME using a suitable etching agent and using the second gate conductor 106 and the spacers 107 as a hard mask. A top surface of the semiconductor substrate 101 and of the semiconductor fin 102 formed therein are exposed through the etching.

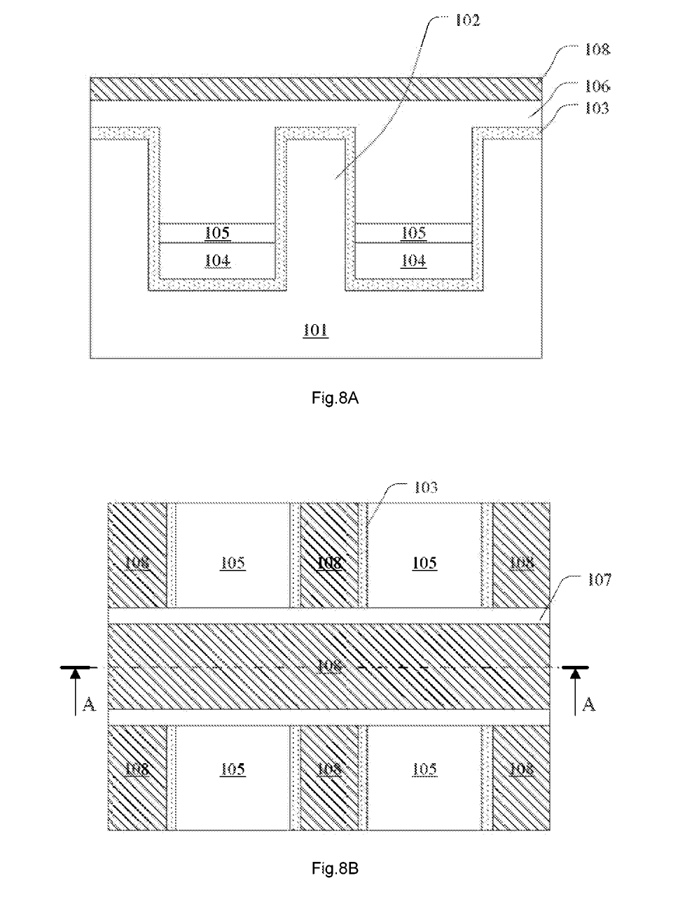

For some embodiments, silicification is performed on a surface of the second gate conductor 106 (if it is formed of silicon) and the exposed surfaces of the semiconductor substrate 101 and the semiconductor fin 102 to form a metal silicide layer 108, in order to reduce contact resistance with the gate, source and the drain regions, as shown in FIGS. 8A and 8B.

Such silicification process is known. As an example, a Ni layer having a thickness of about 5-12 nm is deposited and then subjected to thermal process under 300-500° C. for 1-10 seconds such that NiSi is formed on the surfaces of the second gate conductor 106, the semiconductor substrate 101, and the semiconductor fin 102. Then, remaining parts of the Ni layer are removed by wet etching.

After the steps shown in FIGS. 8A and 8B, an interlayer insulating layer, a plurality of through-holes in the interlayer insulating layer, and at least one wiring or electrode on a top surface of the interlayer insulating layer are formed on an obtained semiconductor structure. The plurality of through-holes enables electrical connections with the second gate conductor 106, the source/drain regions, and the first gate conductor 104, respectively.

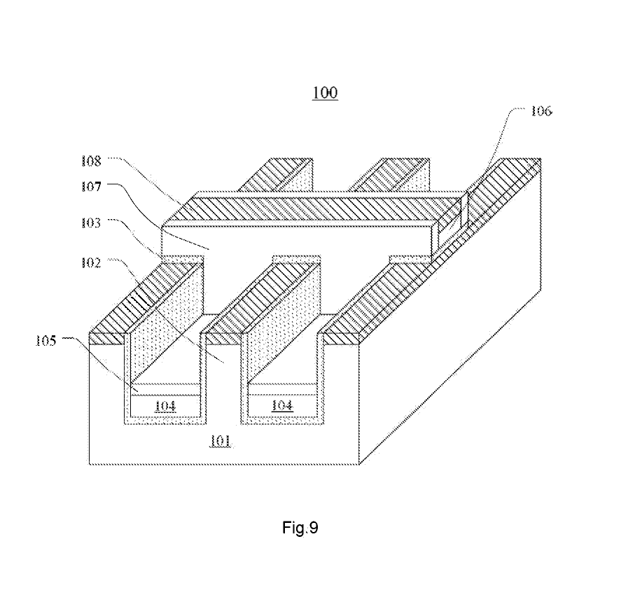

FIG. 9 illustrates a perspective view of a FinFET 100 in accordance with an embodiment of the disclosed technology. The FinFET 100 comprises a semiconductor substrate 101. A semiconductor fin 102 is defined by at least two openings in the semiconductor substrate 101. Source/drain regions (not shown) are formed at opposite ends of the semiconductor fin 102. A gate dielectric 103 is arranged on a top of the semiconductor fin 102 and on a bottom and sidewalls of each opening. A first gate conductor 104, which is arranged within each opening, is adjacent to a bottom of the semiconductor fin 102 and separated from the semiconductor substrate 101 and the semiconductor fin 102 by the gate dielectric 103. An oxide layer 105 is arranged on the first gate conductor 104. A second gate conductor 107 is arranged on the semiconductor fin 102 and separated from the semiconductor fin 102 by the gate dielectric 103. In addition, the oxide layer 105 is configured as an insulating isolation layer for separating the first gate conductor 104 from the second gate conductor 107.

The first gate conductor 104 extends along a direction substantially in parallel with a length direction of the semiconductor fin 102. The second gate conductor 107 intersects the semiconductor fin 102. As an example, the second gate conductor 107 extends along a direction substantially perpendicular to the length direction of the semiconductor fin 102.

For some embodiments, a metal silicide layer 108 may be formed on top of the second gate conductor 107 and the semiconductor fin 102 to reduce the contact resistance.

According to the disclosed technology, bias voltage can be applied to the bottom of the semiconductor fin through the first gate conductor in order to reduce the leakage between the source region and the drain region.

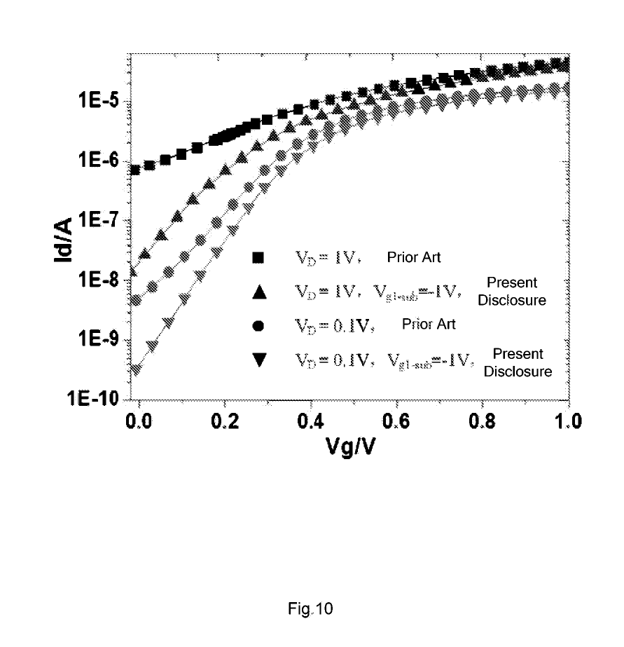

FIG. 10 illustrates a simulation result of a transfer characteristic curve (Id-Vg) of the FinFET in accordance with an embodiment of the disclosed technology. The FinFET according to the disclosed technology comprises the first gate conductor adjacent to the bottom of the semiconductor fin. A bias voltage is applied to the first gate conductor 104. In the example as shown in figure, the bias voltage applied to the first gate conductor 104 with respect to the substrate 101 is V_{g1-sub}=−1V. As shown in the figure, under the same drain voltage (V_{D}=1V or 0V), a leakage current of the FinFET according to the disclosed technology is smaller as compared to that of the FinFET of prior art. Taking a drain voltage V_{D}=1V as an example, the FinFET of prior art has a leakage current I_{off}=7.8e-7 A between source/drain regions when switched off, while the FinFET of the disclosed technology has a leakage current I_{off}=2.0e-8 A between source/drain regions when switched off, which is about 1/30 with respect to the leakage current of the FinFET of the prior art.

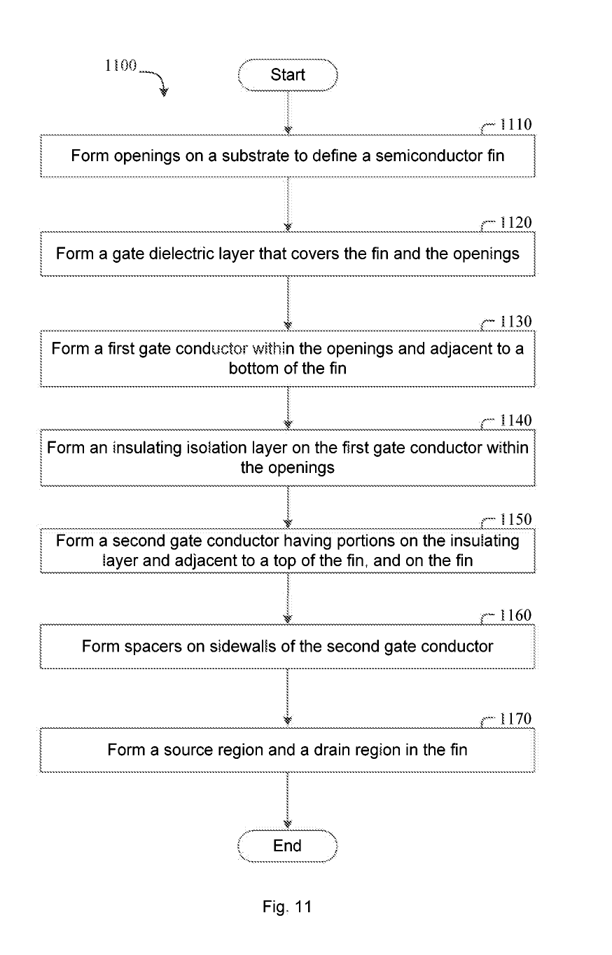

FIG. 11 is a flowchart illustrating a method 1100 for manufacturing a FinFET device according to the disclosed technology. In block 1110, method 1100 forms openings on a semiconductor substrate to define a semiconductor fin. In block 1120, method 1100 forms a gate dielectric layer that covers the fin and the openings. In block 1130, the method 1100 forms a first gate semiconductor within the openings and adjacent to the bottom of the fin. In block 1140, the method 1100 forms an insulating layer on the first gate conductor within the openings. In block 1150, the method 1100 forms a second gate conductor having portions on the insulating layer and adjacent to a top of the fin, and on the fin. In block 1160, the method 1100 forms spacers on sidewalls of the second gate conductor. In block 1170, the method 1100 forms a source region and a drain region in the fin.

The foregoing description does not explain technical details such as patterning and etching of each layer. However, one of ordinary skill in the art will understand that layers and regions of desired shapes can be formed using various processes. Furthermore, processes different from those described above can be used to form the same structure. Features described in various embodiments can be combined for benefit.

The embodiments of the disclosed technology have been described as above. However, these embodiments are explanatory rather than for limiting scope of the disclosed technology. The scope of the disclosed technology is defined by the attached claims and equivalents thereof. One with ordinary skill in the art will understand that various modifications and substitutions can be made to these embodiments without departing from the scope of the disclosed technology.

What is claimed is:

1. A method of manufacturing a FinFET, comprising:
forming, on a semiconductor substrate, a plurality of openings to define a semiconductor fin;
forming a first gate dielectric layer that conformally covers the semiconductor fin and the openings;
forming within the openings a first gate conductor adjacent to a bottom of the semiconductor fin;
forming within the openings an insulating isolation layer arranged on the first gate conductor;
forming a second gate conductor having a first portion on the insulating isolation layer, the first portion adjacent to a top of the semiconductor fin, the second gate conductor having a second portion on the semiconductor fin;
forming spacers on sidewalls of the second gate conductor; and
forming a source region and a drain region in the semiconductor fin.

2. The method according to claim 1, wherein forming the first gate conductor comprises:
forming a conductive layer to at least partially fill the openings; and
etching back the conductive layer selectively, with respect to the first gate dielectric layer, to retain at least a portion of the conductive layer within the openings only, in order to form the first gate conductor.

3. The method according to claim 1, wherein the first gate conductor comprises polysilicon.

4. The method according to claim 1, wherein forming the insulating isolation layer comprises:
forming an insulating layer that fills the openings and covers the top of the semiconductor fin; and
etching back the insulating layer to remove a portion of the insulating layer on the top of the semiconductor fin and retain portions of the insulating layer within the openings, in order to form the insulating isolation layer.

5. The method according to claim 4, wherein forming the insulating layer that fills the openings comprises:
forming the insulating layer through High-Density Plasma deposition, wherein the portion of the insulating layer within each opening has a thickness greater than that of the portion of the insulating layer on the top of the semiconductor fin.

6. The method according to claim 5, wherein the thickness of the portion of the insulating layer formed on the top of the semiconductor fin is smaller than ⅓ of the thickness of the portion of the insulating layer within the opening.

7. The method according to claim 1, wherein forming the second gate conductor comprises:
forming a conductive layer to fill the openings; and
etching the conductive layer selectively with respect to the first gate dielectric layer to form the second gate conductor along a direction intersecting the semiconductor fin.

8. The method according to claim 7, wherein the direction is substantially perpendicular to a length direction of the semiconductor fin.

9. The method according to claim 1, further comprising, between forming the insulating isolation layer and forming the second gate conductor:
removing exposed portions of the first gate dielectric layer; and
forming a second gate dielectric layer which conformally covers the semiconductor fin and the openings.

10. The method according to claim 1, further comprising, between forming the insulating isolation layer and forming the second gate conductor:
forming an interface layer on the first gate dielectric layer; and
forming a second gate dielectric layer which conformally covers the semiconductor fin and the openings and is arranged on the interface layer.

11. The method according to claim 9, further comprising, between forming the second gate dielectric layer and forming the second gate conductor:
forming a work function adjustment layer on the second gate dielectric layer.

12. The method according to claim 1, further comprising, after forming the source region and the drain region:
removing the exposed portions of the first gate dielectric layer using the second gate conductor and the spacers as a mask, in order to expose a top surface of the semiconductor fin; and
performing silicification to form silicide on the top of the second gate conductor and that of the semiconductor fin.

13. A FinFET, comprising:
a semiconductor substrate;
a semiconductor fin formed in the semiconductor substrate;
a source region arranged at a first end of the semiconductor fin;
a drain regions arranged at a second end of the semiconductor fin, the first end and the second end at opposite ends of the semiconductor fin;
a gate dielectric layer arranged on the semiconductor fin;
a first gate conductor adjacent to a bottom of the semiconductor fin;
an insulating isolation layer arranged on the first gate conductor;
a second gate conductor having a first portion on the insulating isolation layer and adjacent to a top of the semiconductor fin and a second portion on the semiconductor fin; and
spacers arranged on sidewalls of the second gate conductor.

14. The FinFET according to claim 13, wherein the first gate conductor extends along a direction substantially in parallel with a length direction of the semiconductor fin.

15. The FinFET according to claim 13, wherein the second gate conductor extends along a direction intersecting the semiconductor fin.

16. The FinFET according to claim 15, wherein the direction is substantially perpendicular to the length direction of the semiconductor fin.

17. The FinFET according to claim 13, wherein the first gate conductor and/or the second gate conductor comprises polysilicon.

18. The FinFET according to claim 13, wherein the insulating isolation layer comprises High-Density Plasma (HDP) oxide.

19. The FinFET according to claim 13, wherein the insulating isolation layer has a thickness of about 10-20 nm.

20. The FinFET according to claim 13, wherein the gate dielectric layer comprises a first gate dielectric layer configured to separate the first gate conductor from the semiconductor fin and a second dielectric layer configured to separate the second gate conductor from the semiconductor fin.
